(19) United States
(12) Patent Application Publication
(10) Pub. No.: US 2005/0181535 A1
(43) Pub. Date: Aug. 18, 2005

(54) Method of fabricating passivation layer for organic devices

(76) Inventors: Sun Jin Yun, Daejeon-city (KR); Jung Wook Lim, Daejeon-city (KR); Young Wook Ko, Daejeon-city (KR); Jin Ho Lee, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/059,854

(22) Filed: Feb. 16, 2005

(30) Foreign Application Priority Data
Feb. 17, 2004 (KR) 10-2004-0010402
Feb. 15, 2005 (KR) 10-2005-0012453

(51) Int. Cl. H01L 21/00; H01L 21/44; H01L 51/40

(52) U.S. Cl. 438/99

(57) ABSTRACT

Provided is a method of fabricating a passivation layer for an organic device, including: forming the organic device on a substrate; and forming a passivation layer on the organic device. Here, forming the passivation layer on the organic device includes forming an inorganic thin film by thin film deposition using pulsed plasma.

### BACKGROUND OF THE INVENTION

This application claims the priority of Korean Patent Application No. 10-2004-0010402, filed on Feb. 17, 2004, and No. 10-2005-0012453, filed on Feb. 15, 2005 in the Korean Intellectual Property Office, the disclosures of which are incorporated herein in their entireties by reference.

1. Field of the Invention

The present invention relates to a method of fabricating passivation layers of a light emitting device and an electronic device (hereinafter referred to as an organic device) including organic materials such as an organic light emitting diode, an organic transistor, or the like, and more particularly, to a method of fabricating a passivation layer at a very low temperature at which organic materials are not denatured.

2. Description of the Related Art

Organic light emitting diodes (OLEDs), which is one of organic devices, can easily realize various colors and obtain high luminance and high luminous efficiency. Thus, the OLEDs draw attentions in the field of display devices. Although there is a difference depending on a material of which such an OLED is formed, the device is deteriorated fast and thus has a short lifetime. The most general deterioration phenomenon is the generation and expansion of dark spots.

The dark spot is more greatly expanded during the operation of the OLED device and continuously deteriorates the organic device even during keeping in the normal environment. In particular, external oxygen and moisture fatally affect the lifetime of the organic device.

Another organic device related to this invention could be organic transistors. The organic materials consisting organic transistors are easily degraded due to the reaction with external oxygen and moisture.

Thus, the improvement of the lifetime of the organic devices such as organic transistors and OLEDs and a passivation layer for passivating the organic devices from moisture and oxygen accelerating the expansion of the dark spots have been become a great issue in the early stage of developing the organic devices. In particular, the passivation layer is much more important when an organic device is formed on a plastic substrate much well permeating moisture and oxygen than when the organic device is formed on a glass substrate.

Currently manufactured bottom-emission OLEDs mainly use SUS metal lid type-encapsulation with a hygroscopic sheet such as BaO₂. However, such SUS metal lid type-encapsulation bears a heavy price burden, and is opaque and inflexible and thus cannot be used in top-emission OLEDs and flexible displays. Thus, a thin film type passivation layer is required so as to be applied to the top-emission OLEDs and the flexible displays and to realize simpler, thinner, and cheaper displays.

As to the thin film type passivation layer, a single layer passivation and a thin passivation are rather advantageous than a multilayer passivation and a thick passivation in terms of manufacturing convenience and cost as far as the characteristics of the thin film type passivation layer are satisfactory. However, according to the results of experiments that was performed using an inorganic thin film such as SiOₓ, SiNₓ, or the like, a single layer cannot sufficiently passitvate an organic device and the characteristics of a multilayer inorganic and/or organic thin films are not satisfactory.

In conventional chemical vapor deposition method, a substrate or an organic device should be heated to form a passivation layer on it. Then, the substrate or the devices sensitive to heat should be deformed and deteriorated. On the other hand, with physical deposition methods such as e-beam evaporation and thermal evaporation, step coverage of the thin film passivation layers is not good, and the density of the thin film type passivation layer is not dense enough to protect the devices from the permeation of gases. Conventional sputter deposition method also results in substrate deformation due to plasma induced-surface heating of organic devices or plastic substrate. Thus, a method of fabricating a high performance passivation layer at a lower temperature is required.

### SUMMARY OF THE INVENTION

The present invention provides a method of fabricating very dense passivation layers of organic devices that are weak to heat and easily deteriorated due to moisture and oxygen.

According to an aspect of the present invention, there is provided a method of fabricating a passivation layer for an organic device, including: forming the organic device on a substrate; and forming a passivation layer on the organic device. Here, forming the passivation layer on the organic device includes: forming an inorganic thin film by thin film deposition method using pulsed plasma at a very low temperature. The passivation layer may enclose the substrate.

Forming the passivation layer utilizing the pulsed plasma may be performed so that the passivation layer encloses the substrate before the organic device is formed on the substrate. Alternatively, forming the passivation layer may be performed before or after the organic device is formed.

The thin film deposition using the pulsed plasma may be plasma enhanced atomic layer deposition, plasma enhanced chemical vapor deposition, or sputter deposition. When the plasma enhanced atomic layer or plasma enhanced chemical vapor deposition method are utilized for depositing the layer, the backside of the substrate can be passivated as well as the front side. An inorganic thin film may be deposited using such a method using pulsed plasma and be combined with an organic thin film so as to form a multi-layered passitvation layer. The pulsed plasma may be a radio frequency, radio frequency-magnetron, electro cyclotron resonance, and inductively coupled plasma type. The inorganic thin film may be a layer formed of Al₂O₃, Al₂O₃:N (including a small amount of N), TiO₂, TiO₂:N (including a small amount of N), SiO₂, SiO₂:N (including a small amount of N), Si₃N₄, ZrO₂, ZrO₂:N (including a small amount of N), a metal(lanthanide group) oxide, or a metal(lanthanide group) oxide including a small amount of N, or a multilayer thin film formed of combinations of Al₂O₃, Al₂O₃:N, TiO₂, TiO₂:N, SiO₂, SiO₂:N, Si₃N₄, ZrO₂, ZrO₂:N, a metal(lanthanide group) oxide, or a metal(lanthanide group) oxide including a small amount of N. The inorganic thin film may be a thin film formed of one or more of Al₂O₃, Al₂O₃:N, TiO₂, TiO₂:N, SiO₂, SiO₂:N, Si₃N₄, ZrO₂, ZrO₂:N, metal(lanthanide group) oxide, or a metal(lanthanide group) oxide including a small amount of N.

According to an aspect of the present invention, forming the inorganic thin film may include periodically repeating a sequential injection cycle of a source gas, purge gas, O₂, and purge gas to form an inorganic oxide layer using atomic layer deposition; and generating very short plasma activating O₂ in synchronization with a supply period of O₂.

According to another aspect of the present invention, forming the inorganic thin film may further include forming an inorganic oxide layer by chemical vapor deposition using a source gas and O₂; and generating pulsed plasma. Here, in general, if plasma is not formed, a layer may not be formed under the experimental conditions such as a low temperature and O₂ gas as the oxidant.

### BRIEF DESCRIPTION OF THE DRAWINGS

The above and other features and advantages of the present invention will become more apparent by describing in detail exemplary embodiments thereof with reference to the attached drawings in which:

FIGS. 1 through 4 are cross-sectional views of organic devices including passivation layers according to an embodiment of the present invention;

FIGS. 5 through 7 are cross-sectional views of various types of passivation layers according to embodiments of the present invention;

FIG. 8 is a view illustrating operations of a method of fabricating a passivation layer according to an embodiment of the present invention;

FIG. 9 is a view illustrating operations of a method of fabricating a passivation layer according to another embodiment of the present invention; and

FIG. 10 is a graph illustrating lifetime curves of an OLED having a passivation layer formed using a pulsed plasma enhanced atomic layer deposition method and an OLED not having a passivation layer.

### DETAILED DESCRIPTION OF THE INVENTION

The present invention will be described more fully hereinafter with reference to the accompanying drawings in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the forms of elements are exaggerated for clarity. To facilitate understanding, identical reference numerals have been used, where possible, to designate identical elements that are common to the figures.

The present invention suggests a method of fabricating a passivation layer by forming an inorganic thin film or a multilayer including the inorganic thin film using pulsed plasma. The passivation layer according to the method of the present invention may be used as a passivation layer of a plastic substrate or a passivation layer of an organic device formed on a flexible substrate such as a plastic or metal foil substrate or a glass substrate. The present invention is characterized by the use of a plasma assisted deposition method of growing a thin film at 150° C. or a temperature much lower than 150° C. unlike a process of depositing a thin film using thermal energy by heating a sample. In particular, very short pulsed plasma can be used to minimize damage caused by plasma without using a plasma deposition method such as existing sputter deposition and continuous plasma enhanced chemical vapor deposition by which a substrate or an organic device sensitive to heat are heated by plasma and thus easily deformed, deteriorated and/or destructed.

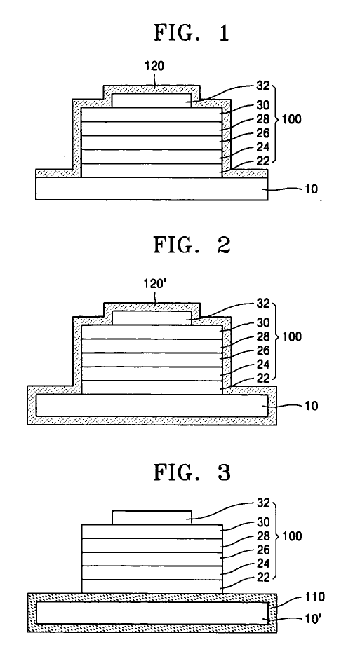

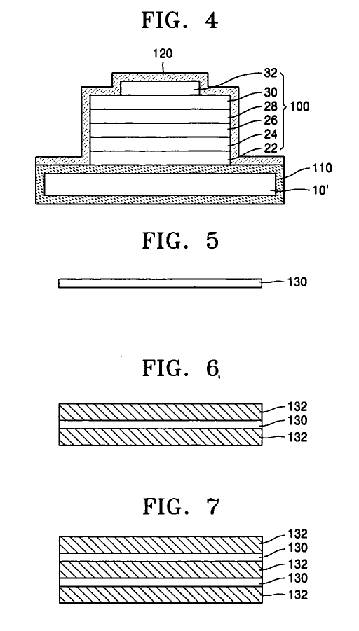

FIGS. 1 through 4 are cross-sectional views of an organic device having a passivation layer according to an embodiment of the present invention. FIG. 1 illustrates an example of forming an organic device 100 on a substrate 10 and then forming a passivation layer 120 on the organic device 100. FIG. 2 illustrates an example of forming a passivation layer 120′ so as to enclose the substrate 10 as well as the organic device 100. FIG. 3 illustrates an example of forming a passivation layer 110 enclosing a substrate 10′ and then the organic device 100 on the passivation layer 110. FIG. 4 illustrates an example of forming passivation layers 1 10 and 120 before or after the organic device 100 is formed on the substrate 10′ so as to enclose both the substrate 10′ and the organic device 100.

The organic device 100 shown in FIGS. 1 through 4 is a typical OLED. The organic device 100 is formed of a stack of an anode 22, a buffer layer 24, a hole transfer layer 26, an emission layer 28, an electron transfer layer 30, and a cathode 32. Such an OLED may be a bottom-emission type OLED or a top-emission type OLED. Although not shown, an organic transistor may be formed of multiple organic layers or several layers of organic layers and inorganic layers. In the FIGS. 1 through 4, the organic device could be an organic transistor.

The thickness of the substrate 10 or 10′ is ranging from several hundred μm to 1 mm, and the type of the substrate 10 or 10′ is not limited to a specific form but may be modified into various forms. For example, if the substrate 10 or 10′ faces light emitting, i.e., the OLED is a bottom-emission type, the substrate 10 or 10′ is a glass or plastic substrate. If the anode 32 faces light emitting, i.e., the OLED is a top-emission type, the substrate 10 or 10′ could be a silicon substrate or an opaque substrate such as metal foil. Even for the top-emitting OLEDs, plastic films can be utilized as substrates for light weight and flexibility. In particular, when the passivation layer 110 encloses the substrate 10′ as shown in FIGS. 3 and 4, the substrate 10′ may be a plastic substrate into which moisture or oxygen permeates easily. Thus, the passivation layer 110 prevents moisture or oxygen from permeating through the substrate 10′ into the organic device 100 such as OLED and organic transistor, etc.

The anode 22 is an electrode injecting holes and has a high work function. In a case where the OLED is a bottom-emission type, the anode 22 is formed of a transparent metal oxide to transmit emitted light to the outside of the organic device 100. A material most widely used to form the anode 22 is an indium tin oxide (ITO) having a thickness of about 50 to 200 nm. The ITO has an optical transparency but is not easily controlled. Thus, the use of chemically-doped conjugated polymers including polythiophene (PT) has been considered in terms of the stability of the surroundings.

The buffer layer 24 supplies the hole transfer layer 26 with holes provided from the anode 22. The hole transfer layer 26 is normally formed of TPD that is a diamine derivative and photoconductive polymer poly(9-vinylcarbazole). The electron transfer layer 30 is formed of an oxadiazole derivative or the like. A combination of the hole and electron transfer layers 26 and 30 can contribute to improving quantum efficiency and lowering a drive voltage through a two-step injection process of transmitting carriers through the hole and electron transfer layers 26 and 30 without directly injecting the carriers. In addition, when electrons and holes injected into the light-emitting (fluorescent or phosphorescent) layer 28 move to an opposite electrode, they are blocked in an opposite transfer layer and thus may be re-combined. As a result, electroluminescence efficiency can be improved.

The light-emitting layer 28 may be formed of a monomolecular organic EL material such as Alq₃, anthracene, or the like or a polymeric organic EL material such as poly (p)-phenylenevinylene (PPV), PT, or derivatives of the PPV and the PT.

The electron transfer layer 30 is formed opposite to the buffer layer 24 and the hole transfer layer 26, the anode 22 injects the holes through the hole transfer layer 26 into the light-emitting layer 28, and the cathode 24 injects the electrons through the electron transfer layer 30 into the fluorescent layer 28. Thus, the electrons and the holes make pairs and are combined to emit energy so as to emit light.

In a case where the OLED is a bottom-emission type, the anode 32 is an electrode injecting electrons and may be formed of a metal having a low work function such as Ca, Mg, Al, or the like. In a case where the OLED is a top-emission type, the anode 32 is a transparent electrode. Here, the use of a metal having a low work function as an electron injection electrode is because a barrier between the anode 32 and the light-emitting layer 28 is lowered to obtain high current density during the injection of electrons. In a top-emission type OLED, totally inverted structure could be constructed on the substrate. Top emission OLED is useful for active matrix-OLED, especially to obtain large emitting area because the light-emitting area should be reduced due to thin film transistors in bottom emission OLED.

The passivation layer 110, 120, or 120′ is formed by depositing an inorganic thin film by thin film deposition method using pulsed plasma. For example, plasma enhanced atomic layer deposition, plasma enhanced chemical vapor deposition, or sputter deposition may be used. Here, the pulsed plasma may be a radio frequency (RF), RF-magnetron, Electro Cyclotron Resonance (ECR), or Inductively Coupled Plasma (ICP) type.

FIGS. 5 through 7 are cross-sectional views of various passivation layers according to embodiments of the present invention.

The passivation layer 110, 120, or 120′ shown in FIGS. 1 through 4 may be formed of an inorganic thin film 130 as shown in FIG. 5, a structure in which the inorganic thin film 130 are sandwiched between organic thin films 132 as shown in FIG. 6, or a structure in which the inorganic thin films 130 and the organic thin films 132 are alternately stacked as shown in FIG. 7.

In the structure of the passivation layer shown in FIGS. 5 through 7, the inorganic thin film 130 may be a layer formed of Al₂O₃, Al₂O₃:N (including a small amount of N), TiO₂, TiO₂:N (including a small amount of N), SiO₂, SiO₂:N (including a small amount of N), Si₃N₄, ZrO₂, ZrO₂:N (including a small amount of N), the a metal(lanthanide group) oxide, or a metal(lanthanide group) oxide including a small amount of N or a multi-layered film formed of combinations of Al₂O₃, Al₂O₃:N (including a small amount of N), TiO₂, TiO₂:N (including a small amount of N), SiO₂, SiO₂:N (including a small amount of N), Si₃N₄, ZrO₂, ZrO₂:N (including a small amount of N), a metal(lanthanide group) oxide, or a metal(lanthanide group) oxide including a small amount of N. Alternatively, the inorganic thin film 130 may be a thin film formed of one or more of Al₂O₃, Al₂O₃:N (including a small amount of N), TiO₂, TiO₂:N (including a small amount of N), SiO₂, SiO₂:N (including a small amount of N), Si₃N₄, ZrO₂, ZrO₂:N (including a small amount of N), a metal(lanthanide group) oxide, or a metal(lanthanide group) oxide including a small amount of N.

In a case where the inorganic thin film 130 is formed of single film, i.e., a layer as shown in FIG. 5, the inorganic thin film 130 can be conveniently manufactured and cost a low manufacturing unit price. The inorganic thin film 130 shown in FIG. 6 can contribute to securing the flexibility of a passivation layer. If necessary, the structure shown in FIG. 6 may be repeatedly stacked as shown in FIG. 7.

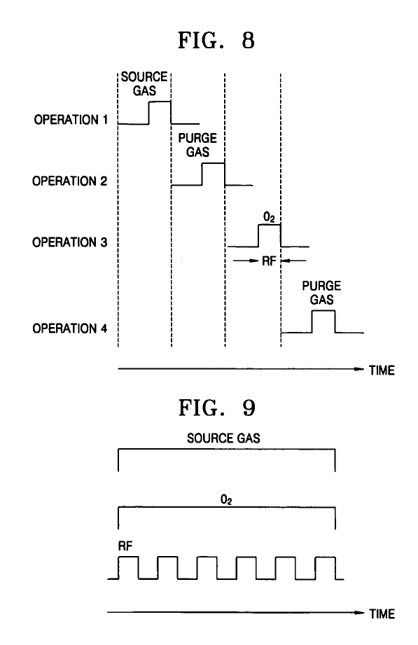

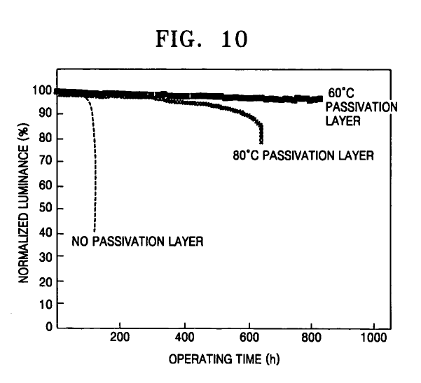

A method of forming the inorganic thin film 130 of a passivation layer of the present invention as shown in FIGS. 5 through 7 by thin film deposition using pulsed plasma will now be described with reference to FIGS. 8 and 9.

FIG. 8 is a view illustrating operations of a method of forming a passivation layer using pulsed plasma enhanced atomic layer deposition. Referring to FIG. 8, in operation 1, a source gas (or vapor) is injected, and then in operation 2, a purge gas (Ar or a mixture of Ar and O₂) is injected. In operation 3, RF-power is applied in the short pulse form with O₂ injection. The RF-power synchronizes with a supply period of O₂ to generate plasma. In operation 4, a purge gas is injected to remove reaction byproducts.

In the method, the source gas adsorbed on the surface of a substrate or an organic device in operation 1 reacts with reactive particles in the pulsed plasma generated in operation 3. As a result, a layer is formed. As described above, the injection of the source vapor and O₂ gas are isolated from each other by purge gas, then short plasma pulse synchronized with a supply period of O₂ gas induces the reaction between the source vapor adsorbed in the surface and reactive species generated in O₂-plasma. As a result, an inorganic thin film is formed layer-by-layer by repeated cycles of operation 1 to 4. The plasma pulse time per cycle to deposit a film could be as short as 0.1 s. The longer plasma pulse would result in higher film density and higher surface temperature. For example, in the deposition of ZrO₂:N using PEALD, a successful film deposition was accomplished with a plasma as short as 0.2 s. However, it would be preferable that the pulse time is 0.1 s-several seconds, more preferably the pulse time is 0.1 s-5 s. If the pulse time is shorter than 0.1 s film would not be formed sufficiently, if the pulse time is longer than several seconds the substrate would be heated.

For example, in a case where an inorganic thin film is an Al₂O₃ layer, a process of forming the inorganic thin film will be as follows.

When a temperature of a substrate is 100° C. or lower and a pressure of a reactor is about 3 Torr, a source gas including Al is diluted with a carrier gas of about 200 sccm and then injected into a side or upper surface of the reactor by opening a valve installed at an entrance of the reactor. After the source gas is injected for 0.1 to 5 seconds, a purge gas is supplied to purge the source gas physically adsorbed on the substrate or remaining in the reactor for 0.1 to 5 seconds. Then, O₂ gas of about 30 to 100 sccm is supplied and RF pulse to synchronize the supply period of O₂ applied so as to generate plasma. RF source power is about 200 to 400 W based on 12-inch wafer. Such a plasma state is maintained for 0.1 to 5 seconds, and the plasma pulse time could be shorter than or same as the injection time of O₂ gas. Then, a purge gas is supplied to purge out the physically adsorbed source gas or the remaining source gas that has not reacted with O₂. After a purge time is maintained for 0.1 to 5 seconds, the source gas is supplied again. One cycle is then ended. The purge time at an interval between supplies of the source gas is adjusted according to the type of the source gas, and the period of one cycle is about 0.5 to 20 seconds.

Since plasma generates reactive species, the plasma facilitates a reaction between an Al source gas adsorbed on a substrate or an organic device and O₂SO as to form an Al₂O₃ layer. Also, since the plasma supplies activation energy to form a thin film, the plasma can contribute to greatly improving the film density and physical characteristics of the thin film.

In particular, as suggested herein, instead of H₂O, O₂ is used as an oxidant so as to perform a low temperature process. In a case where H₂O is used as the oxygen precursor, a device sensitive to moisture is deteriorated, considerable amount of OH group is contained in the oxide film, and excess H₂O molecules are not well desorbed. Thus, as a layer is grown at a low temperature, the density of the layer is quite lower and impurity level is much higher compared to the films deposited at higher temperature. However, when O₂ is used as the oxygen precursor, a dense layer may be formed even at a low temperature. As a thin film is dense, moisture or oxygen may not permeate through the thin film. Thus, the characteristics of the thin film as a passivation layer may be improved. To generate plasma is essential to deposit oxide film using the PEALD and PECVD techniques because O₂ gas could not react with source vapor at the temperatures lower than 300° C.

FIG. 9 is a view illustrating operations of a method of forming a passivation layer using pulsed plasma enhanced chemical vapor deposition. Referring to FIG. 9, a source vapor and O₂ are continuously supplied, but there is a lack of energy as long as the substrate temperature is not high enough to decompose the precursors. Thus, the source gas does not react with O₂. However, when pulsed plasma is applied, reactive particles are formed in the source gas and O₂SO that the source gas reacts with O₂. As a result, a thin film is deposited. Compared to the pulsed plasma enhanced atomic layer deposition suggested in FIG. 8, the pulsed plasma enhanced chemical vapor deposition suggested in FIG. 9 is disadvantageous in terms of step coverage but advantageous in terms of a deposition rate. On the other hand, the film thickness dependents on total plasma-on time regardless the unit plasma pulse time. Thus, you can increase the film density without increasing the total process time as long as the surface heating effect due to plasma is acceptable.

As described above, in a method of forming a passivation layer for an organic device by thin film deposition method using pulsed plasma according to the present invention, a reaction occurs only during the pulsed plasma. Therefore, the surface heating effect due to the plasma is negligible or minimized. Thus, a substrate sensitive to heat such as a plastic substrate can be prevented from being deformed. Also, a much denser passivation layer can be formed compared to a process of forming a passivation layer using only a thermal reaction.

### EXPERIMENTAL EXAMPLE

An OLED including an anode formed of ITO and a cathode formed of Al was formed on a glass substrate. A hole transfer layer, a fluorescent layer, and an electron transfer layer of the OLED are deposited as a NPB (600 Å)/Alq₃ (600 Å)/LiF (10 Å) structure using a vacuum deposition apparatus. An Al₂O₃:N thin film is deposited on the OLED to a thickness of 100 to 300 nm at a temperature between 40° C. and 80° C. using pulsed plasma enhanced atomic layer deposition. The difference of thickness in the range of 100 to 300 nm did not show any considerable differences in the results. The 40° C.-passivation layer also showed the same result as the 60° C.-passivation layer. FIG. 10 is view illustrating lifetime curves of an OLED with a 300 nm thick-passivation layer and an OLED not including a passivation layer.

When the plasma pulse time was 0.5 s and the substrate temperature was 40, 60, and 80° C., the maximum temperature during the deposition process of a 300 nm thick-film was 40, 60, and 85° C., respectively.

A voltage was applied so that a current of 14 mA/cm² flows in specimens. Next, aging characteristics was measured. Luminances of the specimens was about 710±90 cd/m². The luminance of one of the specimens not including a passivation layer was the lowest. On the assumption that the specimens are the same, as the luminance is high, the specimens may be faster deteriorated. Thus, in this experiment, the most loaded specimen is the specimen formed at the temperature of 80° C. The least loaded specimen is the specimen not including the passivation layer.

As shown in FIG. 10, when the voltage was applied, the luminancesi of the specimens were very slowly decreased at an initial stage to be kept high at 95 to 98%. In the case of the specimen not passivated with the passivation layer, the luminance was fast decreased after 50 hours and then decreased to about 40% after about 110 hours.

When 150 hours elapsed, the luminance of the specimen formed at the temperature of 60° C. was 98% of an initial luminance, and the luminance of the specimen formed at the temperature of 80° C. was 97% of the initial luminance. Thereafter, the luminance was decreased by several % and kept. After 650 hours, the luminance of the specimen formed at the temperature of 80° C. was decreased to about 80%. The luminance of the specimen formed at the temperature of 60° C. was kept at 96% or more up to 850 hours, i.e., at an experiment end time. Also, a luminance decrease rate of the specimen formed at the temperature of 60° C. was very good, i.e., about −0.3%/100 hour. According to the result of the Batrix coating, a luminance decrease velocity is about −0.8%/100 hour as suggested by M. S. Weaver et al. (Appl. Phys. Lett. 81, 2929 (2002)) and about −1.9%/100 hour as suggested by A. B. Chwang et al. (Appl. Phys. Lett. 83, 413 (2003)).

In conventional sputter deposition and reactive sputter deposition methods, continuous plasma is normally applied. Then the substrate is heated due to the plasma although the substrate is not intentionally heated at all. Therefore, the use of a pulsed plasma would be very beneficial to deposit a film on the devices or substrate that are easily deformed or deteriorated at a relatively high temperature.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of fabricating a passivation layer for an organic device, comprising:
forming the organic device on a substrate; and
forming a passivation layer on the organic device,
wherein forming the passivation layer on the organic device comprises:
forming an inorganic thin film by thin film deposition using pulsed plasma.

2. The method of claim 1, wherein the thin film deposition using the pulsed plasma is one of plasma enhanced atomic layer deposition, plasma enhanced chemical vapor deposition, and plasma enhanced sputter deposition.

3. The method of claim 1, wherein the pulsed plasma is one of radio frequency, radio frequency-magnetron, electron cyclotron resonance, and an inductively coupled plasma type.

4. The method of claim 1, wherein the inorganic thin film is a layer formed of one of Al₂O₃, Al₂O₃:N (including a small amount of N), TiO₂, TiO₂:N (including a small amount of N), SiO₂, SiO₂:N (including a small amount of N), Si₃N₄, ZrO₂, ZrO₂:N (including a small amount of N), a metal(lanthanide group) oxide, or a metal(lanthanide group) oxide including a small amount of N or a multilayer thin film formed of combinations of Al₂O₃, Al₂O₃:N, TiO₂, TiO₂:N, SiO₂, SiO₂:N, Si₃N₄, ZrO₂, ZrO₂:N, a metal(lanthanide group) oxide, or a metal(lanthanide group) oxide including a small amount of N.

5. The method of claim 1, wherein the inorganic thin film is a thin film formed of one or more of Al₂O₃, Al₂O₃:N, TiO₂, TiO₂:N, SiO₂, SiO₂:N, Si₃N₄, ZrO₂, ZrO₂:N, a metal(lanthanide group) oxide, or a metal(lanthanide group) oxide including a small amount of N.

6. The method of claim 1, wherein forming the passivation layer on the organic device further comprises:
forming an organic passivation thin film on the organic device.

7. The method of claim 6, wherein when the passivation layer is formed on the organic device, forming the organic thin film and forming the inorganic thin film are alternately performed.

8. The method of claim 1, wherein forming the inorganic thin film comprises:
periodically repeating the injection of the source vapor and O₂ gas, that is isolated from each other by purge gas; and
generating O₂ plasma to form reactive species in synchronization with a injection period of O₂ to form an inorganic oxide layer-by-layer using atomic layer deposition.

9. The method of claim 8, the plasma pulse time is in the range of 0.1 to several seconds.

10. The method of claim 1, wherein forming the inorganic thin film further comprises:
forming an inorganic oxide layer by chemical vapor deposition using a source vapor and O₂; and
generating pulsed plasma.

11. The method of claim 1, wherein the passivation layer encloses the substrate.

12. A method for fabricating a passivation layer for an organic device, comprising:
forming the passivation layer enclosing a substrate; and
forming the organic device on the passivation layer,
wherein forming the passivation layer comprises:
forming an inorganic thin film by thin film deposition using pulsed plasma.

13. The method of claim 12, further comprising:
forming another passivation layer on the organic device,
wherein forming the another passivation layer on the organic device comprises:
forming an inorganic thin film by thin film deposition using pulsed plasma.

14. The method of claim 12, wherein the thin film deposition using the pulsed plasma is one of plasma enhanced atomic layer deposition, plasma enhanced chemical vapor deposition, and sputter deposition.

15. The method of claim 12, wherein the pulsed plasma is one of radio frequency, radio frequency-magnetron, electron cyclotron resonance, and an inductively coupled plasma type.

16. The method of claim 12, wherein the inorganic thin film is a layer formed of one of Al₂O₃, Al₂O₃:N, TiO₂, TiO₂:N, SiO₂, SiO₂:N, Si₃N₄, ZrO₂, ZrO₂:N, the a metal(lanthanide group) oxide, or a metal(lanthanide group) oxide including a small amount of N or a multilayer thin film formed of combinations of Al₂O₃, Al₂O₃:N, TiO₂, TiO₂:N, SiO₂, SiO₂:N, Si₃N₄, ZrO₂, ZrO₂:N, the a metal(lanthanide group) oxide, or a metal(lanthanide group) oxide including a small amount of N.

17. The method of claim 12, wherein the inorganic thin film is a thin film formed of one or more of Al₂O₃, Al₂O₃:N, TiO₂, TiO₂:N, SiO₂, SiO₂:N, Si₃N₄, ZrO₂, ZrO₂:N, the a metal(lanthanide group) oxide, or a metal(lanthanide group) oxide including a small amount of N.

18. The method of claim 12, wherein forming the passivation layer on the organic device further comprises:
forming an organic passivation thin film.

19. The method of claim 18, wherein when the passivation layer is formed on the organic device, forming the organic thin film and forming the inorganic thin film are alternately performed.

20. The method of claim 12, wherein forming the inorganic thin film comprises:
periodically repeating the injection of the source vapor and O₂ gas, that is isolated from each other by purge gas; and
generating O₂ plasma to form reactive species in synchronization with a injection period of O₂ to form an inorganic oxide layer-by-layer using atomic layer deposition.

21. The method of claim 12, wherein forming the inorganic thin film further comprises:
forming an inorganic oxide layer by chemical vapor deposition using a source gas and O₂; and
generating pulsed plasma.
